(19) United States
(12) Patent Application Publication
(10) Pub. No.: US 2021/0184085 A1
(43) Pub. Date: Jun. 17, 2021

(54) SIDEWALL SCATTERING FOR RADIATION PATTERN CONTROL OF LEDS

(71) Applicant: Lumileds Holding B.V., Schiphol (NL)

(72) Inventors: Hisashi MASUI, San Jose, CA (US); Kentaro SHIMIZU, Sunnyvale, CA (US); Ryan SPRINGER, San Jose, CA (US); Noad SHAPIRO, Fremont, CA (US)

(21) Appl. No.: 16/712,563

(22) Filed: Dec. 12, 2019

(51) Int. Cl. H01L 33/50; H01L 33/60

(52) U.S. Cl. CPC H01L 33/505; H01L 33/60; H01L 33/502; H01L 27/156; H01L 2933/0041; H01L 2933/0091; H01L 2933/0058

(57) ABSTRACT

Sidewall reflector structures disposed on the sidewalls of an LED or pcLED comprise a thin specular reflection layer and a light scattering layer disposed between the sidewall and the specular reflection layer. These sidewall reflector structures are more diffusively reflective than a specular reflector, yet maintain high reflectivity.

### FIELD OF THE INVENTION

The invention relates generally to phosphor-converted light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

### SUMMARY

This specification discloses LEDs and pcLEDs comprising a top light emitting surface, an oppositely positioned bottom surface, and side walls connecting the top and bottom surfaces. Sidewall reflector structures disposed on the sidewalls comprise a thin specular reflection layer and a light scattering layer disposed between the sidewall and the specular reflection layer.

These sidewall reflector structures are more diffusively reflective than a specular reflector, yet maintain high reflectivity. LEDs and pcLEDs comprising such sidewall reflector structures can exhibit a narrower and more Lambertian radiation output pattern from the top (light emitting surface) than devices employing only specularly reflective sidewall reflectors. In addition, such sidewall reflector structures may be thinner than conventional volume scattering sidewall reflectors, allowing LEDs and pcLEDs employing the sidewall reflector structures disclosed herein to be placed closer to each other than would be the case if volume scattering sidewall reflectors were used.

These LEDs and pcLEDs may be advantageously employed in arrays of closely spaced devices, for example in automobile headlights.

Other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross sectional view of an array of pcLEDs arranged with respect to waveguides and a projection lens. FIG. 4B shows an arrangement similar to that of FIG. 4A, without the waveguides.

FIG. 5 shows a schematic cross-sectional view of an example pcLED employing volume scattering sidewall reflectors.

FIG. 6 shows a schematic cross-sectional view of an example pcLED employing thin film side coat reflectors.

FIG. 7A shows a schematic cross-sectional view of an example pcLED employing sidewall reflectors that comprise a specularly reflective layer and a scattering layer disposed between the specularly reflective layer and the sidewalls of the device.

FIG. 7B shows another schematic cross-sectional view of an example pcLED employing sidewall reflectors that comprise a specularly reflective layer and a scattering layer disposed between the specularly reflective layer and the sidewalls of the device.

FIGS. 8A, 8B, and 8C schematically show steps in an example process for fabricating sidewall reflectors as in FIG. 7A and FIG. 7B.

FIGS. 9A and 9B schematically show steps in another example process for fabricating sidewall reflectors as in FIG. 7A and FIG. 7B.

FIGS. 10A, 10B, 10C, and 10D schematically show steps in another example process for fabricating sidewall reflectors as in FIG. 7A and FIG. 7B.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode structure 102 disposed on a substrate 104, together considered herein an “LED”, and a phosphor layer 106 disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output from the pcLED.

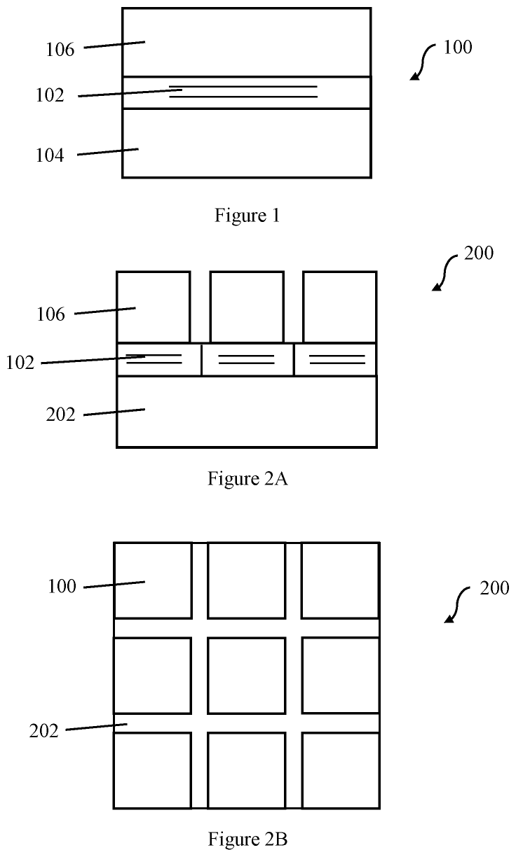

FIGS. 2A-2B show, respectively, cross-sectional and top views of an array 200 of pcLEDs 100 including phosphor pixels 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from separate individual pcLEDs. Substrate 202 may optionally comprise CMOS circuitry for driving the LED, and may be formed from any suitable materials.

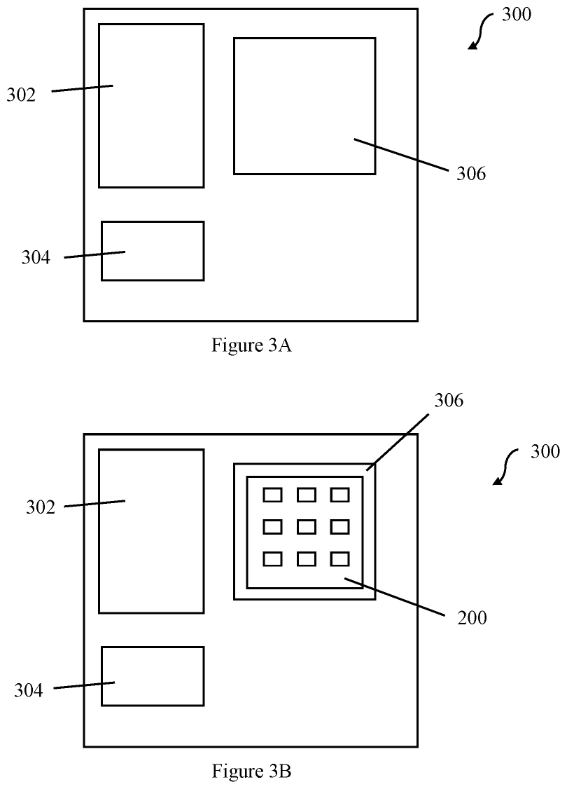

As shown in FIGS. 3A-3B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

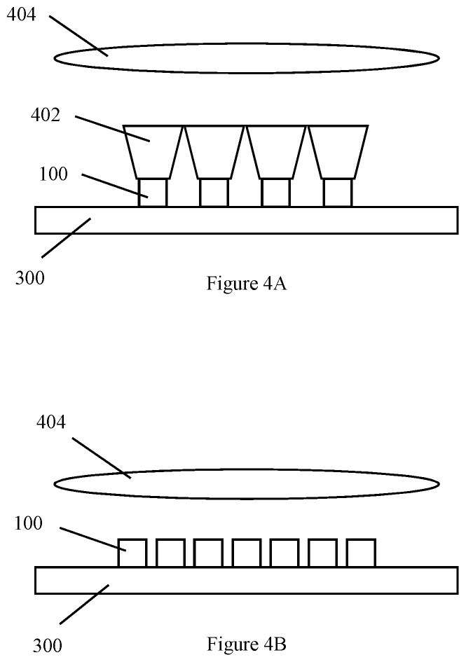

Individual pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B a pcLED array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may particularly be suitable when pcLEDs can be spaced sufficiently close to each other, and may also be used in automobile headlights as well as in camera flash applications. A microLED display application may use similar optical arrangements to those depicted in FIGS. 4A-4B, for example. Generally, any suitable arrangement of optical elements may be used in combination with the pcLEDs described herein, depending on the desired application.

As summarized in the summary section above, this specification discloses thin sidewall reflector structures for LEDs and pcLEDs that can provide an improved radiation output pattern compared to devices employing only specularly reflective sidewall reflectors, yet maintain high reflectivity with a relatively thin reflector structure.

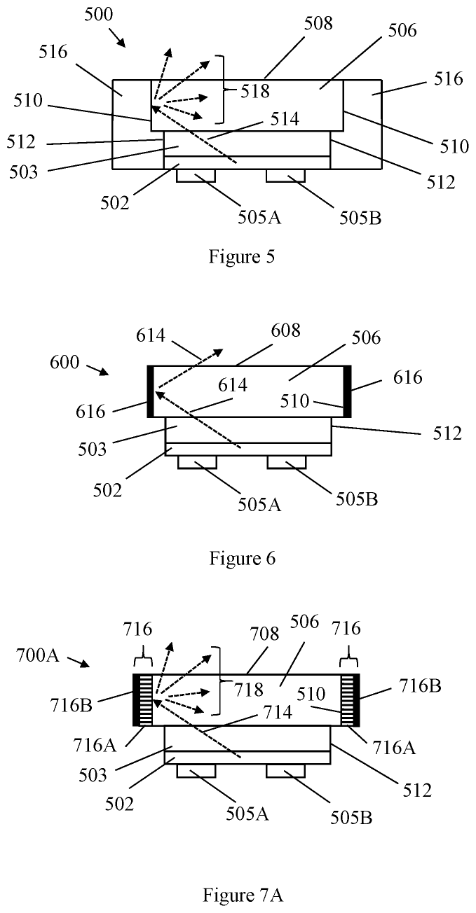

FIG. 5 shows a schematic cross-sectional view of a pcLED 500 comprising a light emitting semiconductor diode 502 disposed on a transparent substrate 503, and a wavelength converting structure 506 disposed on the transparent substrate opposite from the light emitting semiconductor diode. Upon application of a suitable voltage across contacts 505A and 505B semiconductor diode 502 emits light, which may be transmitted through the transparent substrate to the wavelength converting structure. The wavelength converting structure absorbs some or all of the light from the semiconductor diode and in response emits longer wavelength light. Light output through top surface 508 of pcLED 500 may comprise any suitable mixture of light emitted by the light emitting semiconductor diode and light emitted by the wavelength converting structure.

Light emitted by the semiconductor diode or by the wavelength converting structure that is incident on a side wall 510 of the wavelength converting structure (e.g., light ray 514) or on a sidewall 512 of the semiconductor diode and transparent substrate is generally diffusively reflected by volume scattering sidewall reflectors 516 back into and/or out of the device (e.g., light rays 518), so that essentially all light output by pcLED 500 is output through top surface 508.

Light emitting semiconductor diode 502 may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, and II-VI materials.

Transparent substrate 503 is transparent to light emitted by semiconductor diode 502 and to light emitted by wavelength converting structure 506. Transparent substrate 503 may be a sapphire substrate, for example.

Wavelength converting structure 506 may comprise any suitable phosphor material, and may for example be a ceramic phosphor plate or other ceramic phosphor structure formed by sintering phosphor particles. Such a ceramic phosphor plate or structure may exhibit little or no scattering of light emitted by the semiconductor diode or emitted by the wavelength converter.

Volume scattering reflectors 516 may comprise Titanium Oxide particles dispersed in a silicone binder, for example. Volume scattering reflectors 516 may have a thickness of about 30 microns to about 300 microns, for example, measured perpendicularly to the sidewalls.

An advantage of using volume scattering sidewall reflectors as in device 500 is that they are diffusively reflected as illustrated in FIG. 5 and discussed above. As a consequence, the output radiation pattern from top surface 508 is typically Lambertian, which is desirable. A disadvantage to using volume scattering sidewall reflectors is that the thickness of these reflectors required to provide sufficiently high reflection/scattering makes the lateral dimensions of the device significantly larger than those of the light emitting semiconductor diode. This increases the minimum spacing between such devices.

FIG. 6 shows a schematic cross-sectional view of a pcLED 600 that differs from pcLED 500 (FIG. 6) by substituting thin film side coat reflectors 616 for volume scattering reflectors 516. The thin film side coat reflectors 616 may be a reflective metal coating or a Distributed Bragg Reflector (DBR), for example. This film side coat reflectors 616 may have a thickness of about 0.1 microns to about 10 microns, for example.

An advantage to using thin film side coat reflectors 616 is that they may be sufficiently thin that the lateral dimensions of device 600 are not significantly larger than those of the light emitting semiconductor diode. This allows for closer spacing of such devices than is possible for devices employing volume scattering sidewall reflectors.

A disadvantage is that such thin film side coat reflectors are typically specularly reflective rather than diffusively reflective—they reflect light rays at an angle of reflection equal to the angle of incidence (e.g., ray 614). As a consequence, the output radiation pattern from top surface 608 of the device is typically wider than the preferred Lambertian distribution, especially if the wavelength converting structure (for example, a ceramic phosphor structure) does not strongly scatter light. The wider output radiation pattern is commonly disadvantageous when the device is combined with external optics causing low coupling efficiency, meaning increasing unused light. One way of improving the radiation pattern is to increase volume scattering in the wavelength converting structure, but this method typically increases scattering loss in the wavelength converter.

A further disadvantage of using such thin film side coat reflectors is that for light generated in a low-scattering wavelength converter such as a ceramic phosphor platelet, the light can become trapped circulating in an optical cavity due to the specularly reflective nature of the sidewall reflectors.

A difficulty with using thin film side coat reflectors is that typically they must be formed on a smooth supporting surface. This is particularly true for Distributed Bragg Reflectors, which must be formed on a sufficiently smooth supporting surface to minimize transmission loss.

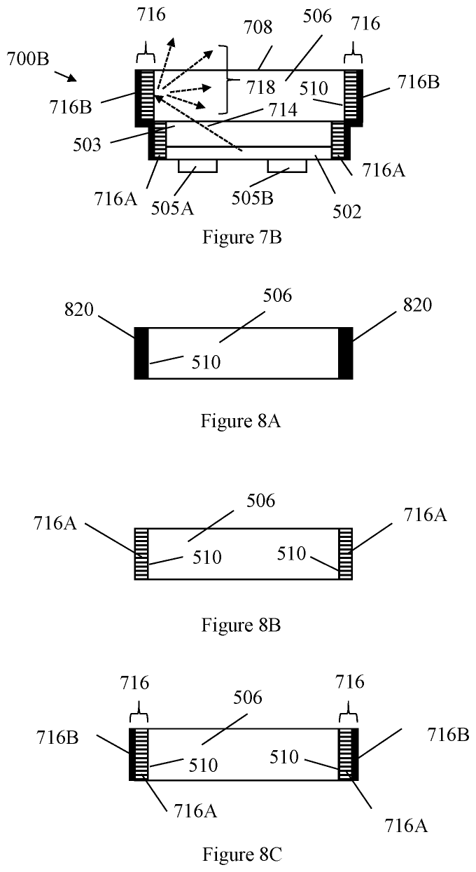

FIG. 7A shows a schematic cross-sectional view of a pcLED 700A in which sidewall reflectors 716 comprise a diffusive or diffractive scattering layer 716A positioned between the sidewall of the wavelength converter and a specularly reflective thin film side coat reflector 716B. Reflective layer 716B is disposed on a smooth outer surface of diffusive or diffractive scattering layer 716A. The smooth outer surface of layer 716A may have for example a surface roughness of Ra≤1 micron, ≤750 nm, or ≤500 nm. Scattering layer 716A may have a thickness of about 1 micron to about 30 microns, for example. Reflector layer 716B may have a thickness of about 0.1 microns to about 10 microns, for example.

The combination of scattering layer 716A and specularly reflective layer 716B maintains high reflectivity while providing a more diffusive reflector, allowing for light to be directed in a random direction or preferentially forward (towards the light output surface) direction. This improves the radiation output pattern through top surface 708 of the device, making the radiation pattern more Lambertian, and also helps prevent optical cavity trapping of light in the wavelength converter.

Specularly reflective layer 716B may be or comprise a reflective metal layer or a Distributed Bragg Reflector, for example. Scattering layer 716A may be or comprise, for example, a porous columnar structure that provides optically diffusive characteristics in the plane perpendicular to the columns, while maintaining a physically smooth outer layer. Alternatively, scattering layer 716A may be or comprise, for example, Titanium Oxide particles dispersed in a silicone binder.

As shown in FIG. 7B, a schematic cross-sectional view of a pcLED 700B, sidewall reflectors 716 may extend to cover side walls of the semiconductor LED and the transparent substrate.

Referring now to FIGS. 8A-8C, in some variations light scattering layers 716A may be formed on sidewalls of a wavelength converting structure 506 (e.g., a ceramic phosphor plate) by depositing and then anodizing an aluminum layer. As shown in FIG. 8A, a layer of aluminum 820 is formed on a sidewall of the wavelength converting structure, for example by RF sputtering. The aluminum layer may be formed on a transparent conductive layer (Indium Tin Oxide, for example) that is first deposited on the sidewall, to facilitate the following anodization step. As shown in FIG. 8B, layer 820 may then be anodized to form a porous alumina light scattering layer 716A comprising columnar structures with long axes oriented away from the sidewall. The physical dimensions of the columnar structures may be slightly smaller than the wavelengths of light emitted by the semiconductor diode and the wavelength converting structure, for example on the order of hundreds of nanometers. The columnar structures may have diameters of 100 nm to 200 nm, for example. Optionally, sputtered SiO₂ can be applied to the porous structures in layer 716A to help seal up the pores and smooth the outer surface of the layer. Fabrication examples of such porously anodized layers possessing columnar structure have been published in Surface and Coatings Technology 169-170 (2003) 190-194, though not for the use and purpose described here. The outer surface of layer 716A is smooth, as described above. As shown in FIG. 8C, specularly reflective layer 716B is then formed on light scattering layer 716A by conventional methods, for example.

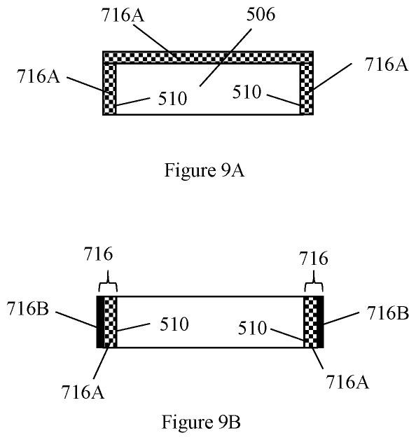

Referring now to FIGS. 9A-9B, in other variations a diffusive light scattering layer 716A is applied to a wavelength converting structure by spray coating or dip coating, optionally followed by a surface smoothening solution based coating. The diffusive light scattering layer may comprise Titanium Oxide particles in a silicone binder, for example. Any suitable light scattering composition may be used. The surface smoothening solution based coating may be implemented, for example, as a conventional sol-gel technique. As shown in FIG. 9A, the light scattering layer may initially be deposited on the sidewalls and top surface of the wavelength converting structure, and subsequently removed from the top surface by conventional methods. The outer surface of layer 716A is smooth, as described above. As shown in FIG. 9B, specularly reflective layer 716B is then formed on light scattering layer 716A by conventional methods, for example.

In other variations a diffusive light scattering layer 716A is applied to a wavelength converting structure by vapor phase deposition, for example pulsed laser deposition, of a dielectric layer comprising light-scattering (e.g., air-filled) voids. The outer surface of layer 716A is made smooth, as described above. Similarly to as shown in FIG. 9B, specularly reflective layer 716B is then formed on light scattering layer 716A by conventional methods, for example.

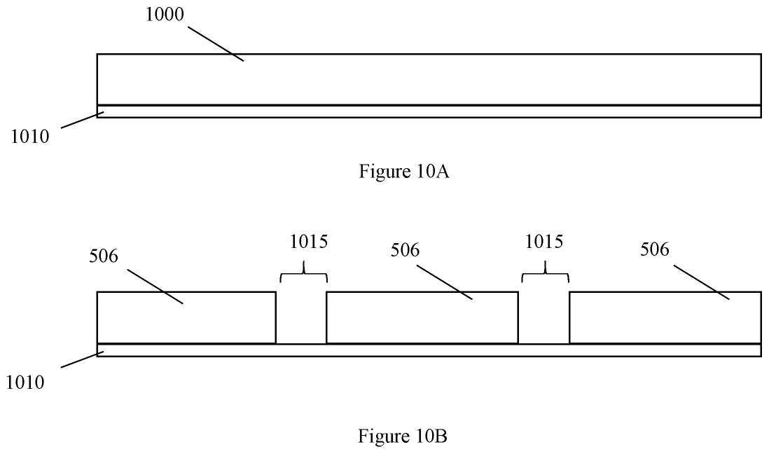

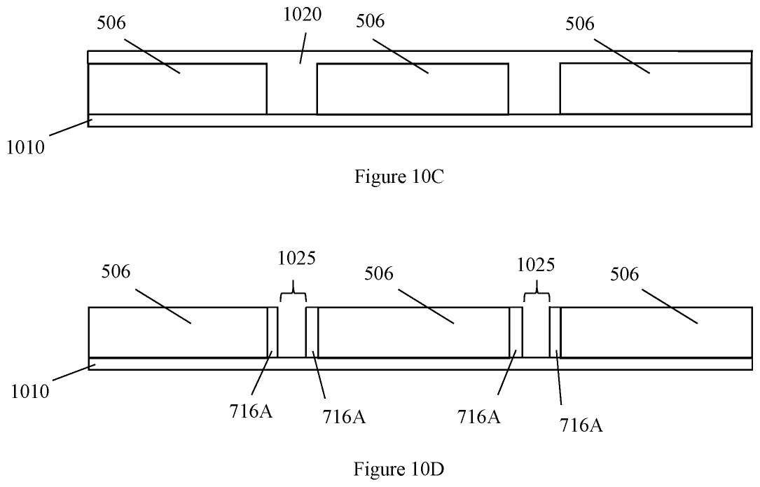

FIGS. 10A-10D illustrate another variation of methods by which smooth-walled diffusive light scattering layers 716A can be fabricated on a ceramic phosphor plate wavelength converting structure. A ceramic phosphor wafer 1000 on a temporary support 1010 as shown in FIG. 10A is sawn into ceramic phosphor platelet wavelength converting structures 506 with, for example, a saw producing wide streets (saw cuts) 1015 as shown in FIG. 10B. The streets may be 100 microns wide, for example, but any suitable street width may be used. As shown in FIG. 10C, the streets are then filled with a light scattering composition 1020, for example phosphor particles and/or Titanium Oxide particles in a silicone binder. This may be done by overmolding with the light scattering mixture, for example. After curing, the filled streets are then re-sawn with a narrower saw to form narrower streets 1025, leaving light scattering layers 716A on sidewalls of the ceramic phosphor platelet wavelength converters as shown in FIG. 10D.

Saw cuts through a ceramic phosphor plate typically leave rough edges, but the saw cuts through the filled streets that define layers 716A leave sufficiently smooth outer surfaces on these layers to support deposition of specular reflective layers 716B, which may be subsequently deposited.

Sidewall reflectors 716 may be formed on a wavelength converting structure 506, and then the wavelength converting structure subsequently attached to a light emitting semiconductor diode or to a transparent substrate on a light emitting semiconductor diode.

Alternatively, sidewall reflectors 716 may be formed on a wavelength converting structure after the wavelength converting structure is attached to a light emitting semiconductor diode or to a transparent substrate on a light emitting semiconductor diode. In that case the sidewall reflectors 716 may be formed to extend to cover sidewalls of the transparent substrate and the light emitting semiconductor diode, as shown for example in FIG. 7B.

Sidewall reflectors 716 may also be formed on sidewalls of a light emitting semiconductor diode and/or side walls of a transparent substrate attached to the light emitting semiconductor diode with no wavelength converting structure attached to the device.

This disclosure is illustrative and not limiting. Further modifications will be apparent to one skilled in the art in light of this disclosure and are intended to fall within the scope of the appended claims.

1. A wavelength converting structure comprising:
a phosphor structure comprising a top surface, an oppositely positioned bottom surface, and side walls connecting the top and bottom surfaces; and
side wall reflectors disposed on or adjacent the sidewalls of the phosphor structure, each side wall reflector comprising a specular reflection layer and a light scattering layer disposed between a sidewall and the specular reflection layer.

2. The wavelength converting structure of claim A1, wherein the phosphor structure is or comprises a ceramic phosphor plate.

3. The wavelength converting structure of claim A1, wherein each light scattering layer is disposed on a corresponding side wall, and each specular reflection layer is disposed on a corresponding light scattering layer.

4. The wavelength converting structure of claim A3, wherein each specular reflection layer is disposed on a surface of the corresponding light scattering layer having a roughness RA less than or equal to 500 nanometers.

5. The wavelength converting structure of claim A1, wherein the light scattering layers comprise columnar structures of Aluminum Oxide having long axes oriented away from the side walls.

6. The wavelength converting structure of claim A1, wherein the light scattering layers comprise light scattering particles disposed in a silicone binder.

7. The wavelength converting structure of claim A1, wherein the specular reflective layers comprise Distributed Bragg Reflectors.

8. The wavelength converting structure of claim A1, wherein the side wall reflectors have total thicknesses less than or equal to about 50 microns perpendicular to the side walls.

9. A light emitting device comprising:
a light emitting diode; and
the wavelength converting structure of claim Al positioned in an optical path of light output from the semiconductor light emitting diode.

10. The light emitting device of claim A9, wherein:
the light emitting diode comprises a transparent substrate having a top surface, an oppositely positioned bottom surface, and side walls connecting the top and bottom surfaces; and
the wavelength converting structure is disposed on the top surface of the transparent substrate.

11. The light emitting device of claim A10, wherein the side wall reflectors extend along and on or adjacent corresponding side walls of the transparent substrate.

12. The wavelength converting structure of claim A11, wherein the phosphor structure is or comprises a ceramic phosphor plate.

13. The wavelength converting structure of claim A1, wherein each light scattering layer is disposed on a corresponding side wall, and each specular reflection layer is disposed on a corresponding light scattering layer.

14. The wavelength converting structure of claim A13, wherein each specular reflection layer is disposed on a surface of the corresponding light scattering layer having a roughness RA less than or equal to 500 nanometers.

15. The wavelength converting structure of claim A14, wherein the light scattering layers comprise columnar structures of Aluminum Oxide having long axes oriented away from the side walls.

16. A method for making a light emitting device, the method comprising:
obtaining or providing a ceramic phosphor plate comprising a top surface, an oppositely positioned bottom surface, and side walls connecting the top and bottom surfaces;
disposing a light scattering layer on each side wall, each light scattering layer comprising an outer surface facing away from its corresponding side wall having a roughness RA less than or equal to 1 micron; and
disposing a specular reflective layer on each light scattering layer outer surface.

17. The method of claim 16, wherein disposing a light scattering layer on each side wall comprises:
disposing an aluminum layer on each side wall; and
anodizing the aluminum layers to form columnar arrangements of aluminum oxide having long axes oriented away from the side walls.

18. The method of claim 16, wherein:
obtaining or providing a ceramic phosphor plate comprises sawing a ceramic phosphor wafer to form streets having widths W1 defining the side walls of the phosphor plate; and
disposing a light scattering layer on each side wall comprises filling the streets with a light scattering composition and sawing streets having widths W2 in the filled streets, where W2<W1, to define the outer surfaces of the light scattering layers.

19. The method of claim 16, comprising disposing the ceramic phosphor plate on a light emitting diode.

20. The method of claim 19, wherein the light emitting diode comprises a transparent substrate, comprising disposing the ceramic phosphor plate on the transparent substrate.
